(19) United States
(12) Patent Application Publication
(10) Pub. No.: US 2002/0044094 A1
(43) Pub. Date: Apr. 18, 2002

(54) System performance for use as feedback control of power supply output of digital receiver when receiver is operated in a standby mode

(76) Inventor: Brian Douglas May, Carmel, IN (US)

Correspondence Address: THOMSON multimedia Licensing Inc., Patent Operations, Two Independence Way, P.O. Box 5312, Princeton, NJ, 08543-5312, US

(21) Appl. No.: 09/893,114

(22) Filed: Jun. 27, 2001

Related U.S. Application Data
(60) Provisional application No. 60/233,189, filed on Sep. 15, 2000.

(51) Int. Cl. G01R 1/00

(52) U.S. Cl. 343/703

(57) ABSTRACT

The electrical energy consumed by digital receiver systems (e.g., direct-broadcast-satellite (DBS) receiver systems) that are continuously operational either in a standby mode or, alternatively, in an active mode is significantly reduced by deriving a feedback signal, in response to a signal received by the receiver system when operated in its standby mode, that defines a measurable system-performance value (e.g., bit-error-rate status value) that is a function of the value of the system's energization. Such significant reduction is accomplished by employing a memory and microprocessor for effecting the reduction in the value of standby-mode energization to that certain value at which the measurable system-performance value is at least an acceptable system-performance value which is significantly below a maximum system-performance value.

### CROSS REFERENCE TO RELATED APPLICATION

This application claims priority of U.S. Provisional Application Ser. No. 60/233,189 filed Sep. 15, 2000.

### BACKGROUND

1. Field of the Invention

This invention relates to a power supply.

2. Description of the Prior Art

It is well known in the art to save the amount of energy consumed by electrically-powered apparatus by switching the apparatus from its active mode to its standby mode when it is not being actively used by an operator thereof. For example, to save energy, a personal computer (PC), permanently connected on-line to a service provider for collecting information, is often equipped with a programmable power management feature wherein the PC monitor, in a standby mode, is deenergized automatically after the PC operator has stopped using the PC for a certain period of time, but immediately resumes its active mode in response to the operator operating a key or the “mouse” of the PC computer.

Further, known in the art are microwave distribution systems comprising a group of satellite transponders for transmitting a set of digital television-channel signals to each of a large number of highly directive dish-like antennas of individual direct-broadcast-satellite (DBS) receivers, in which the television-channel signals are transmitted on circularly-polarized radio frequency (RF) carrier signals in the Ku-band microwave frequency range (e.g., 12,200 to 12,700 MHz). A first sub-set of the digital television signals received by each DBS receiver are right-hand circularly polarized (RHCP) and a second sub-set of the digital television signals received by each DBS receiver are left-hand circularly polarized (LHCP). A low noise block (LNB) converter down-converts the range (“block”) of relatively high frequency microwave carrier signals transmitted by the transmitter to a more manageable lower range of RF frequencies (e.g., 950 to 1450 MHz). Typically, the LNB converter is part of an outdoor unit which includes the receiving reflector antenna and the LNB converter. A DBS receiver also comprises an integrated receiver-decoder (IRD) chassis located indoors which is coupled to and continuously energizes the outdoor LNB converter with a DC voltage so long as the IRD is connected to an AC power source. As known in the art, the polarization response of the LNB converter to the RF carrier signals applied thereto is a function of the magnitude of the energizing DC voltage coupled thereto. More specifically, the LNB converter responds to (1) the first subset of RHCP carrier signals if the magnitude of the DC energizing voltage is within a relatively low first range of magnitudes, (2) the second subset of LHCP carrier signals if the magnitude of the energizing DC voltage is within a relatively high second range of magnitudes and (3) a transition between the RHCP and LHCP carrier signals if the magnitude of the DC energizing voltage is above its first range of magnitudes but below its second range of magnitudes. Further, when a user-controlled switch in the IRD chassis is in its closed switch position, the IRD operates in its active mode. Otherwise, the IRD operates in its standby mode.

Included in each of the set of digital television-channel signals continuously transmitted by each of the group of satellite transponders to a DBS receiver is so-called (1) currently-updated on-screen-display (OSD) information listing all the programs of each of all of the set of the television channels to be received over the next given time period (e.g., 3 hours) and (2) system status information. The IRD of a DBS receiver includes an OSD memory for storing the current OSD information, thereby permitting the user at any time to read out and display the current OSD information in the active mode which is being collected continuously.

The first operation by the user in installing a newly acquired prior-art DBS receiver is to plug in the DBS receiver to an AC power source. The second operation by the user in installing the newly acquired prior-art DBS receiver is to accurately point the highly directive reflector antenna of the DBS receiver toward the particular location in the sky of a satellite. To accomplish this second operation, the user observes a displayed status related to the received bit-error rate and then moves the highly directive reflector antenna into that spatial position at which the displayed status value is optimized. For purposes of these discussions, the widely understood terminology “bit-error rate” is used to describe system performance. In order to aid the user accomplish this second operation, a worst case is assumed and the response sensitivity of the prior-art DBS receiver is maximized by supplying relatively high fixed-value DC voltages in each of the first and second ranges for use by the LNB converter.

For environmental reasons as well as the reason of reducing electrical energy costs for consumers, it is the policy of both the government and industry to promote the reduction of the consumption of electrical power in this country by eliminating the electrical-power waste that currently takes place. In this regard, there are now many millions of DBS receivers in use and in the near future many millions more of DBS receivers will be in use.

Therefore, there is a specific need for automatically adjusting any individual DBS receiver during the installation thereof to effect the minimization of the value of standby power consumed by that individual DBS receiver, while maintaining the bit-error rate at a still acceptable value, which is significantly higher than the minimum value. There is a more general need to effect the minimization of the value of standby power consumed by any type of individual digital receiver, which has the added advantage of requiring lower heat dissipation from the structure of that individual digital receiver. The present invention is directed to meeting these needs.

### SUMMARY OF THE INVENTION

The invention is directed to an improvement in a digital receiver system, such as a DBS digital receiver, in which the system comprises (1) a power supply for energizing the receiver system with a value of energization, (2) first means for operating the receiver system either in an active mode or, alternatively, in a standby mode and (3) second means responsive to a signal received by the receiver system for deriving a measurable system-performance value that is a function of the value of energization. The improvement comprises third means coupled to the power supply and responsive to the measurable system-performance value when the receiver system is being operated in its standby mode for reducing the value of energization to that certain value at which the measurable system-performance value is no greater than a given threshold value, where the given threshold value provides an acceptable system-performance value which is significantly below a maximum system-performance value.

A power supply, embodying an inventive feature includes a data signal processing circuit energized by an output supply for producing a data signal. The data signal has a bit-error that is determined by the output supply. A bit error detector is responsive to the data signal for generating a signal indicative of a magnitude of the bit-error in the data signal. A power supply regulator is coupled to a source of an input supply for generating the output supply in a feedback manner, in response to the bit-error magnitude indicative signal.

### BRIEF DESCRIPTION OF THE DRAWING

FIG. 1 is a block diagram of a DBS receiver;

FIG. 2 is a block diagram of (1) the structural combination of the indoor standby components of the IRD-chassis block shown in FIG. 1 which are relevant to the present invention, (2) the outdoor components block shown in FIG. 1 and (3) and the coupling between them; and

FIG. 3, together with FIGS. 3a, 3b and 3c, are block diagrams of those logical-flow steps performed manually by the user and those logical-flow steps performed automatically under the control of the microprocessor and memory shown in FIG. 2.

### DESCRIPTION OF THE PREFERRED EMBODIMENTS

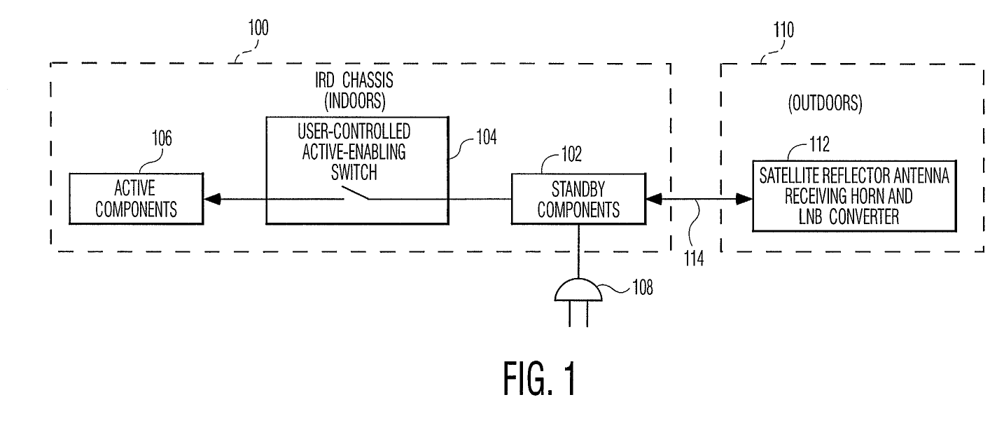

Referring to FIG. 1, there is shown indoor-located IRD chassis 100, comprising standby components block 102, user-controlled active-enabling switch block 104 and active components block 106. As long as AC plug 108 is plugged into a source of AC power, standby components block 102 will be energized. However, active components block 106 will be energized only when the user-controlled active-enabling switch of block 104 is in its closed switch position. Also shown in FIG. 1 is outdoor-located components 110 comprising reflector antenna, receiving horn and LNB converter block 112. As indicated by two-headed arrow 114 coupling blocks 102 and 112 together, an energized standby components 102 supplies energization to the LNB converter of block 112, while the down-converted RF output from the LNB converter of block 112 is applied as an input to standby components 102.

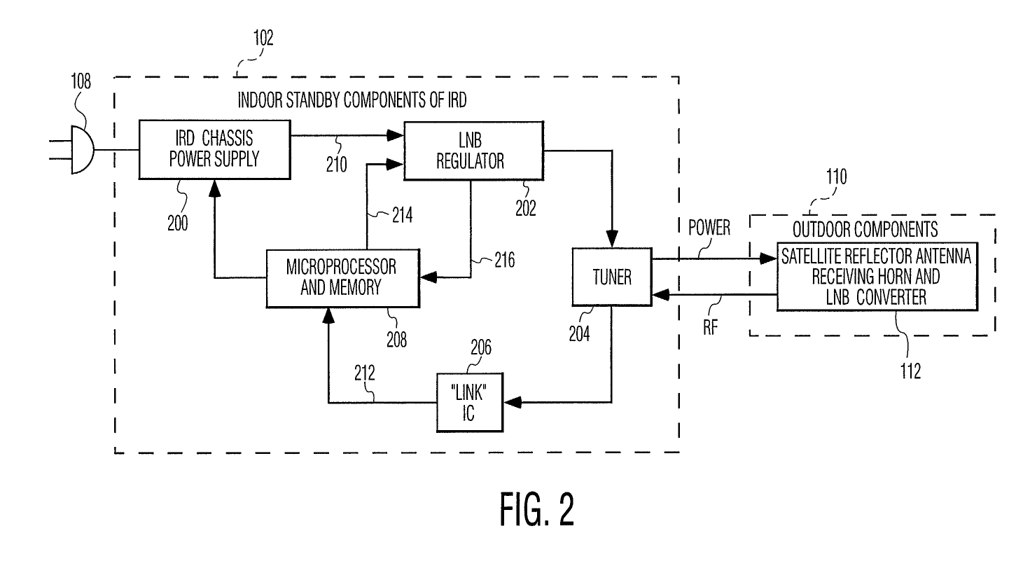

Referring now to FIG. 2, there is shown the structure of coupled blocks 102 and 112 in more detail. Specifically, block 102 in FIG. 2 shows indoor standby components 102 as comprising IRD chassis power supply 200 (which is energized so long as AC plug 108 is plugged into a source of AC voltage), LNB regulator 202, tuner 204, so-called “link” integrated circuit (IC) 206 and microprocessor and memory 208, which are combined to function with one another in accordance with the principles of the present invention. The structure of standby components 102, in practice, also includes additional blocks that perform functions which are not relevant to the present invention and, therefore, have been left unshown in FIG. 2. Further, while the indoor standby components of prior-art DBS receivers may comprise components generally similar to components 200, 202, 204, 206 and 208 of FIG. 2, these indoor standby components of prior-art DBS receivers are not combined to function with one another in accordance with the principles of the present invention.

In the case of prior-art DBS receivers, the IRD chassis power supply thereof supplies a relatively high first fixed-magnitude DC voltage (e.g., 22 DCV) output as an input to the LNB regulator thereof. To select digital signals in the RHCP first subset, the LNB regulator derives a relatively-low second fixed-magnitude DC voltage (e.g., 13 DCV) output from the first fixed-magnitude voltage applied as an input thereto. To select digital signals in the LHCP second subset, the LNB regulator derives a third relatively-high fixed-magnitude DC voltage (e.g., 18 DCV) output from the first fixed-magnitude voltage applied as an input thereto. The selected fixed-magnitude DC voltage output from the LNB regulator is forwarded through the tuner to the power input of the outdoor-located LNB converter to both energize the LNB converter and select either the RHCP first subset or, alternatively, the LHCP second subset. The particular value of the relatively-low second fixed-magnitude DC voltage (e.g., 13 DCV) is chosen to substantially maximize the sensitivity response of the LNB converter to digital signals in the RHCP first subset and the particular value of the relatively-high third fixed-magnitude DC voltage (e.g., 18 DCV) is chosen to substantially maximize the sensitivity response of the LNB converter to digital signals in the LHCP second subset.

In the case of the DBS receiver of the present invention, IRD chassis power supply 200 supplies a DC voltage having a first programmable magnitude as a first input to LNB regulator 202 over conductor 210. LNB regulator 202, in turn, derives a DC voltage first output having a second programmable magnitude which selectively corresponds to a digital signal in the RHCP first subset or, alternatively, a digital signal in the LHCP second subset, which is forwarded through tuner 204 to the power input of the outdoor-located LNB converter of block 112.

In response thereto, the outdoor-located LNB converter of block 112 derives a down-converted RF carrier output which is returned to indoor standby components 102 and applied as a signal input to tuner 204. Tuner 204 derives an in-phase (I)/quadrature-phase (Q) bit stream output therefrom that is applied as an input to “link” IC 206. “Link” IC 206 derives a plurality of outputs including an I/Q bit-streaming error-correction output, a decryption output and an MPEG-encoding output, which are not shown in FIG. 2, and a bit-error rate status output which, as shown in FIG. 2, is applied as an input to microprocessor and memory 208 over conductor 212. The memory of component 208 includes both non-volatile memory (e.g., flash memory), which retains stored data even when AC plug 108 is unplugged, and volatile memory, in which stored data is erased when AC plug 108 is unplugged. Among the data stored in the non-volatile memory is (1) the nominal LNB regulator voltage value and the nominal RHCP voltage value which, when employed, result in substantially maximizing the response sensitivity of the LNB converter, (2) a first threshold value T₁ which is equal to the very high value of the bit-error rate which occurs whenever the magnitude of the DC voltage energizing the LNB converter is above its first range of magnitudes but below its second range of magnitudes, thereby being indicative of a transition occurring between the RHCP and LHCP carrier signals, and (3) a second threshold value T₂ which is equal to an acceptable value for the bit-error rate (e.g., 1 bit error per 1,000,000 bits), which acceptable value is still high compared to the minimum value for the bit-error rate that occurs when the magnitude of the DC voltage energizing the LNB converter in each of the first and second range has a value that substantially maximizes the response sensitivity of the LNB converter to a digital signal in the RHCP first subset or, alternatively, a digital signal in the LHCP second subset.

Applied as an input to IRD chassis power supply 200 is a first data output from microprocessor and memory 208 for controlling the first programmable magnitude of the DC voltage supplied from power supply 200 as the first input to LNB regulator 202 over conductor 210. Applied as a second input to LNB regulator 202 over conductor 214 is a second data output from microprocessor and memory 208 for controlling the second programmable magnitude of the DC voltage supplied as the first output from LNB regulator 202 which is forwarded through tuner 204 to the power input of the outdoor-located LNB converter of block 112. LNB regulator 202 also derives an open/short flag as a second output therefrom which is applied over conductor 216 as a second input to microprocessor and memory 208 to indicate either a short or an open circuit occurring outside IRD 100 which may be used for system failure diagnostics.

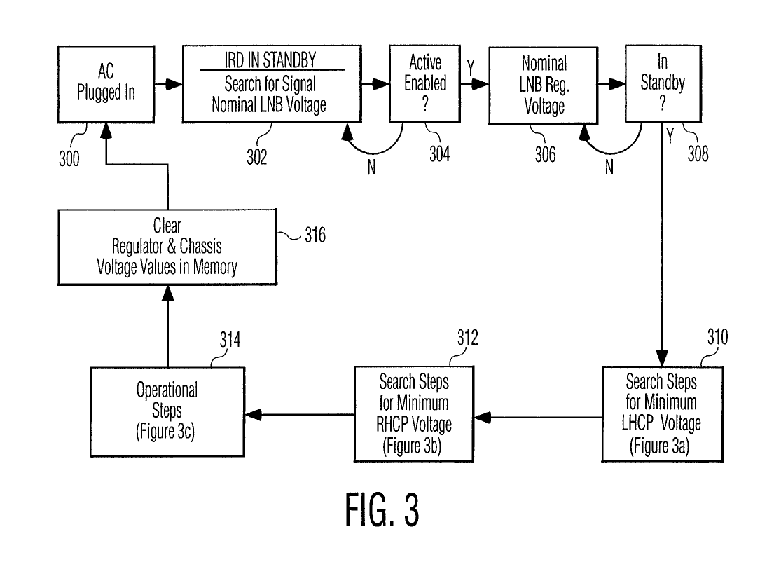

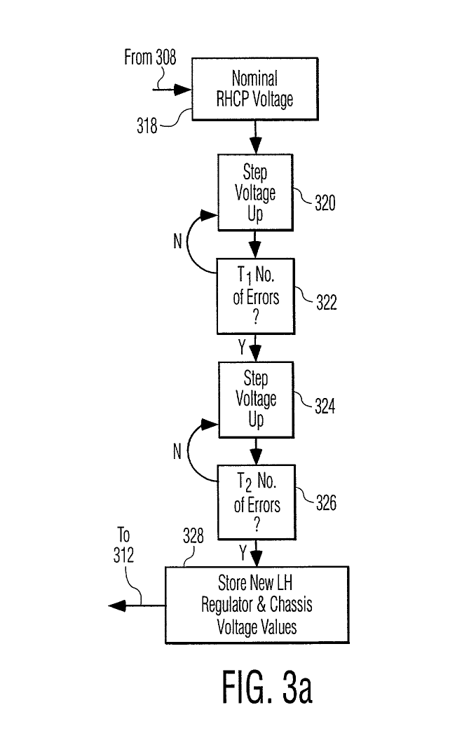

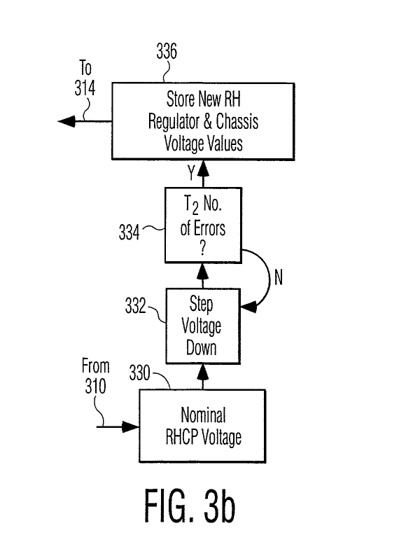

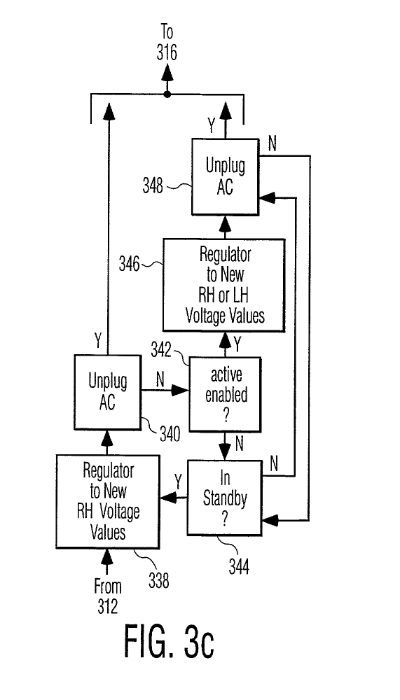

The operation of the FIG. 2 structure in implementing the principles of the present invention are indicated by the logical-flow steps shown in FIGS. 3, 3a, 3b and 3c, where the designation “N” is used to indicate that the answer to the asked question (?) is No and the designation “Y” is used to indicate that the answer to the asked question is Yes.

As shown in FIG. 3, the first step, indicated by block 300, is for the user to determine that AC plug 108 has been plugged into an AC power source. If AC plug 108 is plugged in and block 304 indicates that active components 106 are not enabled because switch 104 is in its open switch position, the IRD is in its standby mode as indicated by block 302. In that case, microprocessor and memory 208 should be receiving a bit-error rate status input over conductor 212 that is indicative of the fact that the LNB converter is energized by a nominal LNB voltage and is deriving an RF signal output therefrom. However, if block 304 indicates that active components 106 are enabled because switch 104 is in its closed switch position, microprocessor and memory 208 then controls IRD chassis power supply 200 to deliver a programmed DC voltage to the input of LNB regulator having the stored nominal value, thereby maximizing the response sensitivity of the LNB converter when active components 106 are enabled to permit the user to go through the set-up procedure of accurately pointing the highly directive dish-like antenna of the DBS receiver toward the particular location in the sky of a satellite. Thereafter, when the IRD has been returned by the user to its standby mode, as indicated by block 308, microprocessor and memory 208 successively performs (1) the search steps shown in FIG. 3a for minimum LHCP voltage, as indicated by block 310, (2) the search steps shown in FIG. 3b for minimum RHCP voltage, as indicated by block 312 and (3) the operational steps shown in FIG. 3c, as indicated by block 314.

Referring now to FIG. 3a, block 318 indicates that microprocessor and memory 208 initially controls the value of the second programmable magnitude of the DC voltage supplied as the first output from LNB regulator 202 to be equal to the value of the stored nominal RHCP, which causes the bit-error rate status input to microprocessor and memory 208 over conductor 212 to have a minimum value. Blocks 320 and 322 indicate that microprocessor and memory 208 continuously compares the current bit-error rate value to the very high threshold value T₁ and in response to this comparison controls both the IRD chassis power supply 200 and LNB regulator 202 to continuously step up the magnitudes of the programmable voltage outputs therefrom, thereby causing the bit-error rate value to continuously increase, until the bit-error rate value is increased to the point where it becomes equal to the very high threshold value T₁. This occurs when the LNB converter is operating at the transition point between RHCP carrier signals and LHCP carrier signals.

As indicated by block 324, the step up of the magnitudes of the programmable voltage outputs from both the IRD chassis power supply 200 and LNB regulator 202, continues even after the transition point between RHCP carrier signals and LHCP carrier signals has been reached. However, now the carrier signals derived by the LNB converts are the LHCP carrier signals and, therefore, the bit-error rate value continuously decreases as the magnitudes of the programmable voltage outputs from both the IRD chassis power supply 200 and LNB regulator 202 continue to increase. As indicated by block 326, this continuous increase persists until the comparison of the current bit-error rate value with the relatively high, but acceptable, threshold value T₂ shows that the threshold value T₂ has been reached. As indicated by block 328, the respective values of the magnitudes of the left-hand (LH) programmable voltage outputs from both the IRD chassis power supply 200 and LNB regulator 202 that result in the current bit-error rate value becoming equal to the relatively high, but acceptable, threshold value T₂ are stored in the volatile memory of microprocessor and memory 208. It is apparent that these stored voltage magnitude values are smaller than the voltage magnitude values (e.g., 18 VDC) which would result in a maximum sensitivity response and a minimum bit-error rate value in the LHCP carrier signals derived by the LNB converter.

Referring now to FIG. 3b, block 330 indicates that microprocessor and memory 208 initially controls the value of the second programmable magnitude of the DC voltage supplied as the first output from LNB regulator 202 to be equal to the value of the stored nominal RHCP, which causes the bit-error rate status input to microprocessor and memory 208 over conductor 212 to have a minimum value. Blocks 332 and 334 indicate that microprocessor and memory 208 continuously compares the current bit-error rate value to the relatively high, but acceptable, threshold value T₂ and in response to this comparison controls both the IRD chassis power supply 200 and LNB regulator 202 to continuously step down the magnitudes of the programmable voltage outputs therefrom, thereby causing the bit-error rate value to continuously increase, until the bit-error rate value is increased to the point where it becomes equal with the relatively high, but acceptable, threshold value T₂. As indicated by block 336, the respective values of the magnitudes of the right-hand (RH) programmable voltage outputs from both the IRD chassis power supply 200 and LNB regulator 202 that result in the current bit-error rate value becoming equal to the relatively high, but acceptable, threshold value T₂ are stored in the volatile memory of microprocessor and memory 208. It is apparent that these stored voltage magnitude values are smaller than the voltage magnitude values (e.g., 13 VDC) which would result in a maximum sensitivity response and a minimum bit-error rate value in the RHCP carrier signals derived by the LNB converter.

The nominal value of the current supplied by IRD chassis power supply 200 to LNB regulator 202 and the LNB converter is substantially 200 milliamperes (mA). The above-described prior-art DBS receiver employs fixed-valued LH regulator and chassis voltages of 18 VDC and 22 VDC, respectively, resulting in an LNB converter power consumption of 0.2×18=3.6 Watts (W) and a total power-supply consumption of 0.2×22=4.4 W. Similarly, the above-described prior-art DBS receiver employs fixed-valued RH regulator and chassis voltages of 13 VDC and 22 VDC, respectively, resulting in and an LNB converter power consumption of 0.2×13=2.6 W and a total power-supply consumption of 0.2×22=4.4 W. However, in the case of the present invention, assuming that a voltage drop of 1 DCV occurs in LNB regulator 202, illustrative values for the stored new LH regulator and chassis minimum voltages, indicated by block 328 of FIG. 3a, are 15.5 VDC and 16.5 VDC, respectively, resulting in an LNB converter power consumption of 0.2×15.5=3.1 W and a total power-supply consumption of 0.2×16.5=3.3 W. Similarly, illustrative values for the stored new RH regulator and chassis minimum voltages, indicated by block 336 of FIG. 3b, are 9.0 VDC and 10.0 VDC, respectively, resulting in an LNB converter power consumption of 0.2×9.0=1.8 W and a total power-supply consumption of 0.2×10.0=2.0 W. Thus, while in the LH case, the use of the present invention reduces the total power-supply consumption by only the relatively small amount of 4.4 W-3.3 W=1.1 W, in the RH case, the use of the present invention reduces the total power-supply consumption by the relatively large amount of 4.4W-2.0 W=2.4 W. For this reason, only the RH case is employed while the DBS receiver is operating in its standby mode, since this saves the most energy because normally the IRD is operated by the user in its active mode only a minority of the time and is operated by the user in its standby mode a majority of the time.

More specifically, after the block 310 search steps for minimum LHCP voltage, shown in above-described FIG. 3a, and the block 312 search steps for minimum RHCP voltage, shown in above-described FIG. 3b, have been completed and both the LH and RH regulator and chassis voltage values have been stored in the volatile memory of microprocessor and memory 208, the DBS receiver becomes operational in either its active or standby mode, depending on whether user-controlled active-enabling switch 104 is in its closed switch position or its open switch position, and remains operational until AC plug 108 is unplugged from the AC power source. To achieve relatively low energy consumption of the IRD when operating in its active mode and yet still insure that the bit-error rate has an acceptable value for active-mode operation, it is essential that both the relatively-lower RH and the relatively-higher LH regulator and chassis voltage values stored in the volatile memory of microprocessor and memory 208 be employed. However, the lowest energy consumption of the IRD when operating in its standby mode is achievable by employing only the relatively-lower RH regulator and chassis voltage values stored in the volatile memory of microprocessor and memory 208 without exceeding an acceptable bit-error rate value for standby-mode operation.

In this regard, the operational steps of block 314, shown in FIG. 3, comprise the logical-flow steps performed by blocks 338, 340, 342, 344, 346 and 348 of FIG. 3c. More particularly, solely the new RH regulator and chassis voltage values stored in the volatile memory of microprocessor and memory 208 are read out and applied, respectively, as the programmable voltage values from LNB regulator 202 and on conductor 210 from IRD chassis power supply 200 (as indicated by block 338 of FIG. 3c, which receives its input from the output of block 312 of FIG. 3). If blocks 340 and 348 indicate that AC plug 108 has not been unplugged and block 342 indicates that the active mode has not been enabled, block 344 indicates that the IRD is being operated in its standby mode. This standby-mode operation continues until either block 340 or 348 indicates that the AC has been unplugged or block 342 indicates that the active mode has been enabled. If AC plug 108 has been unplugged, the RH regulator and chassis voltage values stored in the volatile memory of microprocessor are erased (so that replugging AC plug in requires all of the above-described flow steps of FIG. 3 be repeated). If block 342 indicates that the active mode has been enabled, either the new RH or, alternatively, the new LH regulator and chassis voltage values (depending on the television channel selected by the user) are read out from storage in the volatile memory of microprocessor and memory 208 and applied, respectively, as the programmable voltage values from LNB regulator 202 and on conductor 210 from IRD chassis power supply 200 (as indicated by block 346 of FIG. 3c).

While the present invention is primarily directed to a DBS receiver system, it extends to any receiver system, digital or analog, which employs (1) a power supply for energizing the receiver system with a value of energization, (2) first means for operating the receiver system either in an active mode or, alternatively, in a standby mode, (3) second means responsive to a signal received by the receiver system for deriving a measurable system-performance value that is a function of the value of energization and (4) third means coupled to the power supply and responsive to the measurable system-performance value when the receiver system is being operated in its standby mode for reducing the value of energization to that certain value at which the measurable system-performance value is no greater than a given threshold value, where the given threshold value provides an acceptable system-performance value which is significantly below a maximum system-performance value. Without limitation, such digital receiver systems include those that use set-top boxes, MMDS receivers, such personal-computer (PC) associated devices as cable modems, data-service receivers, telephone modems, and GEOCAST receivers.

What is claimed is:

1. A power supply, comprising:
a data signal processing circuit energized by an output supply for producing a data signal, said data signal having a bit-error that is determined by said output supply;
a bit error detector responsive to said data signal for generating a signal indicative of a magnitude of said bit-error in said data signal; and
a power supply regulator coupled to a source of an input supply for generating said output supply and for regulating a magnitude of said output supply in a feedback manner, in response to said bit-error magnitude indicative signal.

2. A power supply according to claim 1, wherein said data signal contains one of a video information signal and an audio information signal.

3. A power supply according to claim 1, wherein when said bit-error magnitude is lower than a first threshold value, said output supply magnitude is reduced, in a feedback manner, to a lower magnitude, in which said bit-error magnitude is higher than said first threshold value.

4. A power supply according to claim 1, wherein said bit error detector generates a signal indicative of a magnitude of a bit-error rate in said data signal.

5. A power supply according to claim 1, wherein a change in said magnitude of said output supply is established in successive steps.

6. A power supply according to claim 5, wherein said power supply selectively operates in a normal, run mode of operation and in a standby mode of operation and wherein said successive steps are performed, outside said normal, run mode of operation.

7. A power supply according to claim 1, wherein said data signal processing circuit processes a direct-broadcast-satellite input signal of a direct-broadcast-satellite receiver system.

8. A power supply according to claim 7, wherein said direct-broadcast-satellite receiver system further includes, an antenna coupled to a low-noise block converter for producing said data signal, and wherein said bit-error has a value that is a function of said magnitude of a power-supply voltage which energizes said low-noise block converter.

9. A power supply according to claim 8, wherein a set of signals received by said antenna comprises a first sub-set of left-hand circularly polarized signals and a second sub-set of right-hand circularly polarized signals.

10. A digital receiver system, comprising:
a power supply for energizing said receiver system with a value of energization;
first means responsive to a signal received by said receiver system for deriving a measurable system-performance value that is a function of said value of energization; and
second means coupled to said power supply and responsive to said measurable system-performance value for reducing said value of energization to that certain value at which said measurable system-performance value is at least an acceptable system-performance value which is below a maximum system-performance value.

11. The digital receiver system defined in claim 10, wherein said digital receiver system is a direct-broadcast-satellite receiver system.

12. The digital receiver system defined in claim 11, wherein said second means includes an antenna and a low-noise block converter having a given output response to a given set of signals received by said antenna that have been transmitted from at least one satellite transponder, wherein said given output response is a function of the value of a power-supply-derived voltage which energizes said low-noise block converter and wherein said first means in response to an output signal from said low-noise block converter derives a feedback signal that defines a bit-error-rate-status value that constitutes said measurable system-performance value.
